(19) United States
(12) Patent Application Publication
(10) Pub. No.: US 2024/0420004 A1
(43) Pub. Date: Dec. 19, 2024

(54) METHODS AND SYSTEMS FOR ANALOGUE QUANTUM COMPUTING

(71) Applicant: SILICON QUANTUM COMPUTING PTY LIMITED, Kensington, New South Wales (AU)

(72) Inventors: Samuel Keith Gorman, Kensington, New South Wales (AU); Michelle Yvonne Simmons, Kensington, New South Wales (AU); Joris Keizer, Kensington, New South Wales (AU); Helen Geng, Kensington, New South Wales (AU); Yousun Chung, Kensington, New South Wales (AU); Matthew Donnelly, Kensington, New South Wales (AU); Mitchell Kiczynski, Kensington, New South Wales (AU); Casey Myers, Kensington, New South Wales (AU); Sam Sutherland, Kensington, New South Wales (AU)

(73) Assignee: SILICON QUANTUM COMPUTING PTY LIMITED, Kensington, New South Wales (AU)

(21) Appl. No.: 18/703,333

(22) PCT Filed: Oct. 24, 2022
(86) PCT No.: PCT/AU2022/051275

§ 371 Date: Apr. 20, 2024

(30) Foreign Application Priority Data
Oct. 24, 2021 (AU) 2021903398
Jun. 22, 2022 (AU) 2022901715

(51) Int. Cl. G06N 10/40; G06F 30/20; G06F 30/3308

(52) U.S. Cl. CPC G06N 10/40; G06F 30/20; G06F 30/3308

(57) ABSTRACT

Aspects of the present disclosure are directed to fabrication methods for analogue quantum systems (AQSs). Further aspects of the present disclosure are directed to methods for solving computational problems using an AQS. Methods for fabricating an AQS include generating a Hamiltonian based on a computational problem, which may be an optimization problem or a simulation problem. Further, the method includes identifying AQS fabrication parameters based on one or more identified measurement methods and the Hamiltonian. Lastly, an AQS can be fabricated based on the identified fabrication parameters. An AQS may be used inter alia to simulate a battery or interfaces.

### TECHNICAL FIELD

Aspects of the present disclosure are related to quantum computing and more particularly to methods and systems for analogue quantum computing.

### BACKGROUND

With recent advances in the development of quantum computing platforms, the possibility of exploiting quantum devices for realistic simulations of complex quantum systems and for solving optimization problems is becoming a reality.

It is not yet possible to implement fully fault tolerant quantum algorithms. However, quantum simulations are possible, but quantum noise and decoherence significantly limit the number of operations that could be performed efficiently on existing platforms. This is what nowadays is called the NISQ (Noisy Intermediate-Scale Quantum) era where simulations or optimizations on quantum computers are possible but the algorithms and tasks need to adapt to noise. Because of this noise, many standard algorithms cannot be performed in quantum computing devices while others appear particularly suited in the NISQ context. For example certain simulation and optimization problems are particularly suited to the NISQ context.

Quantum computing systems that are purpose-built (or hard coded) to perform one or more specific problems are called analogue quantum computers. Such analogue quantum computers have recently been built to realise the Fermi-Hubbard model, to simulate magnetism, and to simulate topological phases. However, it is often very difficult to design and build such analogue quantum computers to solve specific simulation or optimization problems.

### SUMMARY

According to a first aspect of the present invention, there is provided a method for fabricating an analogue quantum system, the method comprising: generating a Hamiltonian based on a computational problem in respect of which a solution is sought using one or more identified measurement methods; identifying analogue quantum system fabrication parameters for the analogue quantum system based on the one or more identified measurement methods and the Hamiltonian; and fabricating the analogue quantum system based on the identified analogue quantum system fabrication parameters.

According to a second aspect of the invention, there is provided a method for fabricating an analogue quantum system for simulating a battery, the method comprising: generating a Hamiltonian based on the computational problem of simulating the battery; identifying system fabrication parameters for the analogue quantum system based on the Hamiltonian and measuring a voltage and/or capacitance between a first quantum dot array and a second quantum dot array typically using a four-point probe measurement; and fabricating the analogue quantum system based on the identified system fabrication parameters.

According to a third aspect of the invention, there is provided a method for fabricating an analogue quantum system for simulating at least one interface, the method comprising: generating a Hamiltonian based on the computational problem of simulating an interface; identifying system fabrication parameters for the analogue quantum system based on the Hamiltonian and measuring a voltage and/or capacitance between at least one interface between a first quantum dot array and a second quantum dot array typically using a four-point probe measurement: and fabricating the analogue quantum system based on the identified system fabrication parameters.

According to a fourth aspect of the invention, there is provided a method for solving a computational problem, the method comprising: providing an analogue quantum system comprising: an array of quantum dots simulating a Fermi-Hubbard model, a plurality of control gates to vary the Hubbard Hamiltonian parameters, and one or more source and drain leads to measure the current through the array of quantum dots: applying a selected measurement method to measure one or more properties of the analogue quantum system: and interpreting the measured one or more properties of the analogue quantum system to determine a solution to the computational problem.

According to a fifth aspect of the invention, there is provided a method for solving a computational problem of simulating a battery, the method comprising: providing an analogue quantum system comprising: at least two arrays of quantum dots simulating a Fermi-Hubbard model, a plurality of control gates to vary Hubbard Hamiltonian parameters, and one or more source and drain leads to measure the current through the array: measuring a voltage and/or capacitance, using a four-point probe measurement, between the first quantum dot array and the second quantum dot array; and interpreting the measured voltage and/or capacitance of the analogue quantum system to determine a solution to the computational problem.

According to a sixth aspect of the invention, there is provided a method for solving a computational problem of simulating at least one interface, the method comprising: providing an analogue quantum system comprising: at least two arrays of quantum dots simulating a Fermi-Hubbard model, an interface defined between the at least two arrays of quantum dots; a plurality of control gates to vary the Hubbard Hamiltonian parameters, and one or more source and drain leads to measure the current through the at least two arrays of quantum dots; applying a four-point probe measurement to measure a voltage and/or capacitance across the interface; and interpreting the measured voltage and/or capacitance of the analogue quantum system to determine a solution to the computational problem of simulating at least one interface.

Further aspects of the present disclosure and embodiments of the aspects summarised in the immediately preceding paragraphs will be apparent from the following detailed description and from the accompanying figures.

### BRIEF DESCRIPTION OF THE DRAWINGS

Features and advantages of the present invention will become apparent from the following description of embodiments thereof, by way of example only, with reference to the accompanying drawings, in which:

FIGS. 1A and 1B show two example prior art donor quantum dot systems.

FIG. 2 shows an example Analogue Quantum System (AQS) according to aspects of the present disclosure.

FIG. 3 illustrates some exemplary one-dimensional, two-dimensional and three-dimensional quantum dot array structures.

FIG. 4 is a flowchart illustrating an example method for determining fabrication parameters for an AQS according to aspects of the present disclosure

FIG. 5 is a flowchart illustrating an example method for using an AQS according to aspects of the present disclosure.

FIGS. 6A to 6D are schematics showing different measurement techniques applied to different analogue quantum systems to measure selected properties of the AQS.

FIG. 7A shows an example one-dimensional lattice with staggered tunnel couplings in the trivial phase.

FIG. 7B shows an example one-dimensional lattice with staggered tunnel couplings in the topologically non-trivial phase.

FIGS. 8A and 8B show exemplary AQS devices for simulating the SSH model for the topologically trivial phase and topologically non-trivial phases, respectively.

FIG. 8C shows an example linear arrangement of quantum dots, source lead, drain lead and gates.

FIG. 9A shows a STM micrograph of an AQS device to simulate the topologically trivial phase of the SSH model.

FIG. 9B shows a schematic of the protocol used to align the quantum dots in the quantum dot array.

FIG. 9C shows an example of the individual gate sweeps on the first iteration (top set of plots) and tenth iteration (bottom set of plots) for a constant source drain bias.

FIG. 9D shows the voltage on each gate per iteration.

FIG. 9E shows the maximum current measured on each gate sweep per iteration.

FIG. 10A shows a theoretical map of the normalised log (conductance) as a function of the ratio of tunnel couplings (with the inter-site Coulomb interactions given by a 1/d^{1.5} dependence, where d is the quantum dot separation), with Device I given by the dashed red line and Device II given by the dashed blue line.

FIG. 10B shows the conductance trace obtained at zero source drain bias, while shifting the electrochemical potentials of all quantum dots, in the trivial phase.

FIG. 10C shows the occupation probability of the many-body eigenenergies of the Hubbard model as a function of the combined gate voltage for the trivial configuration.

FIG. 10D shows the extracted values of Sᵢ from the experimental results are used to obtain the parameters from the Hubbard model and compared theoretical values.

FIG. 10E shows conductance trace obtained at zero source drain bias, while shifting the electrochemical potentials of all quantum dots, in the non-trivial phase.

FIG. 10F shows that in the topological phase the quarter-filling gap almost disappears completely with a sharp transition from the m+4 to m+6 states given by only two conductance peaks separated by ˜0.2 meV.

FIG. 10G shows the occupation probability of the many-body eigenenergies of the Hubbard model as a function of the combined gate voltage for the non-trivial phase.

FIG. 11 shows four example interfaces between two quantum dot arrays. The interfaces may have no disorder, atomic disorder or continuous disorder.

FIG. 12A shows a schematic of a Hall bar measurement designed to measure the equilibrium voltage between two quantum dot arrays simulating battery operation.

FIG. 12B shows a plot of the equilibrium voltage as a function of tuning of a gate voltage.

### DETAILED DESCRIPTION

In quantum mechanics, the Hamiltonian of a system is an operator corresponding to the total energy of that system, including both kinetic energy and potential energy. Its spectrum, the system's energy spectrum or its set of energy eigenvalues, is the set of possible outcomes obtainable from a measurement of the system's total energy. Due to its close relation to the energy spectrum and time-evolution of a system, it is of fundamental importance in most formulations of quantum theory.

The Hubbard model is an approximate model used that describes iterant, interacting electrons (or fermions) on a set of spatially localised orbitals on a lattice. The Hubbard model plays a paradigmatic role in understanding electronic correlations in quantum materials in the field of solid-state physics. It may be used to describe the transition between conducting and insulating systems, particularly for systems with strong electron correlations. The Hubbard model is a simple model of interacting particles in a lattice, with only two terms in the Hamiltonian: a kinetic term allowing for tunneling (“hopping”) of particles between sites of the lattice and a potential term consisting of an on-site interaction. If interactions between particles at different sites of the lattice are included, the model is often referred to as the “extended Hubbard model”. In particular, the Hubbard term, most commonly denoted by U represents the on-site interaction energy and V represents the inter-site interaction energy. The kinetic hopping term is denoted t and may include nearest neighbour hopping and/or hopping between further separated lattice sites.

The general nearest neighbour Hubbard Hamiltonian is given by:

$$H = {\sum }_{〈 i , j 〉} {t}_{i j} {c}_{i}^{†} {c}_{j} + {\sum }_{i} {U}_{i} {n}_{i} ( {n}_{i} - 1 ) + {\sum }_{i < j} {V}_{i j} {n}_{i} {n}_{j} - {\sum }_{i} {μ}_{i} {n}_{i} \qquad ( 1 )$$

Where, the electron hopping term (tᵢⱼ) is related to the tunnelling probability of an electron between lattice sites. The intra-site Coulomb interactions (Uᵢ) is the energy required to add a second electron to a site. The inter-site Coulomb interaction (Vᵢⱼ) is the energy required to add an electron to a neighbouring site-includes interactions over all pairs of sites i and j. Lastly, μᵢ is the chemical potential at site i. The operators cᵢ^{†} are cᵢ are the fermionic creation and annihilation operators for the i^{th} site, nᵢ=cᵢ^{†}c is the number operator for site i, and Σ_{<i,j>} denotes a sum over neighbouring sites i and j. For large enough Uᵢ>>Vᵢⱼ, tᵢⱼ, μᵢ, one ensures that nᵢ∈{0, 1}. It will be appreciated that the model shown above is a spinless model that does not take the spin of electrons into consideration. However, aspects of the present disclosure need not be limited to this type of model and can just as easily be implemented based on a spinful Hubbard Hamiltonian.

It is clear from equation 1 that the general Hubbard Hamiltonian can be thought of as comprising: an electron hopping term [symbol] tᵢⱼcᵢ^{†}cⱼ, an onsite electron correlation term ΣᵢUᵢnᵢ(nᵢ−1), an inter-site electron correlation term Σ_{i<j}Vᵢⱼnᵢnⱼ, and an electrochemical term Σᵢμᵢnᵢ.

Despite its apparent simplicity, the Hubbard model has shown to be able to predict a wide range of complex phenomena related to condensed matter physics and chemistry. Unfortunately, finding the ground state energy of a system described by the Hubbard model is known to be computationally difficult even using a quantum computer. Therefore, the ability to simulate even small size instances of the Hubbard model is of great interest across many scientific fields.

Semiconductor quantum dots offer a highly controllable platform that can be used to directly simulate the Hubbard model in a solid-state architecture. Phosphorus-doped silicon quantum dots in particular have strong interactions due to their small physical sizes allowing many fundamental condensed matter phases to be studied. Since these quantum dots may directly simulate the Hubbard model, which has shown to be Quantum Merlin-Arthur (QMA)-complete, they can be used to perform multiple simulation and optimization problems as these problems can typically also be defined by the Hubbard model.

Some aspects of the present disclosure provide a new method to determine device fabrication parameters to build an analog quantum system (AQS) to solve a specific computational problem. Further, aspects of the present disclosure provide methods for using the fabricated AQS to solve specific computational problems.

To build the AQS, aspects of the present disclosure initially identify one or more measurement methods to obtain a solution based on a given computational problem that needs to be solved. For example, based on a given computation problem such as a quadratic continuous optimization problem, it may be determined that the solution of the problem lies in measuring the ground state energy of a quantum dot array and the current through the quantum dot array. In other examples, it may be determined that the solution of a computation problem can be determined by measuring the electron transmission probability of the AQS, measuring a voltage and/or capacitance across at least one quantum dot array using a four-point probe measurement, or measuring the electron occupation of qubits of the AQS.

The identified measurement method and the Hubbard Hamiltonian can then be used to identify certain device fabrication parameters (e.g., number/geometry of gates/source/drains/sensors, number of device layers/dimensionality of the device, number of quantum dots, size of dots, arrangement of quantum dots etc.). Once the device fabrication parameters are identified in this manner, the AQS can be fabricated.

To perform the computation, the given computational problem is mapped onto the Hubbard Hamiltonian to find a solution of the computation problem by performing the identified measurement method. Where the parameters of the Hubbard Hamiltonian comprise the hopping term (t), the intra-site correlation energy (U), the inter-site correlation energy (V), the chemical potential (μ). In addition to the Hamiltonian parameters other factors also may affect the device fabrication parameters, for example, the temperature of the system, (T) and the global external magnetic field strength (B).

In particular, in aspects of the present disclosure, by changing the geometry of quantum dots and/or electrochemical potential of the dots in the AQS using electrostatic gates, relevant parameters of the Hubbard Hamiltonian can be varied, which is known to be difficult to simulate classically. For example, the on-site energy, U, of the Hubbard Hamiltonian can be varied from 1-100 meV by changing the size of the quantum dots in the AQS. The tunnel coupling parameter, t, can be varied from 0.001-10 meV by changing the inter-dot separation/geometry in the AQS. The energy levels, μ, of the Hubbard Hamiltonian can be varied by changing single-particle energy levels over multiple bands. As such, the electrochemical potential terms (proportional to ni) can be varied in energy much larger than U, V, and t. Inter-site energy, V, of the Hubbard Hamiltonian can be varied from 0.01-20 meV by changing inter-dot separation/geometry. Temperature, T, can be varied from 0.01-50K by changing the electron temperature. Further, the global external magnetic field, γB, (γ is the electron gyromagnetic rati) can be varied from 0-1 meV and the electron filling can be varied across multiple values of the onsite electron interaction term.

### Example AQS

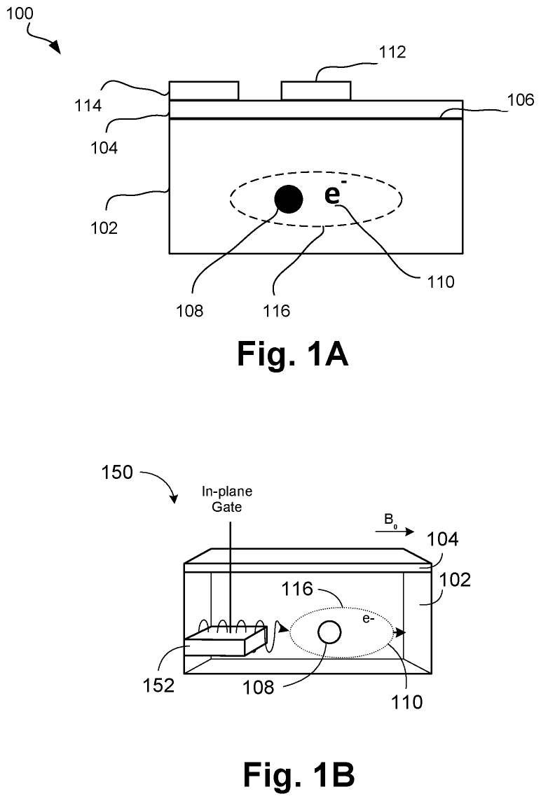

FIG. 1A shows an example semiconductor quantum dot that can be implemented in the AQS of the present disclosure. As shown in the figure, the quantum dot device 100 is formed in a structure comprising a semiconductor substrate 102 and a dielectric 104. In this example, the substrate is isotopically purified silicon (Silicon-28) and the dielectric is silicon dioxide. In other examples, the substrate may be silicon (Si). Where the substrate 102 and the dielectric 104 meet an interface 106 is formed. In this example, it is a Si/SiO₂ interface. To form the quantum dot 100, a donor atom 108 is located within the substrate 102. The donor atom 108 can be introduced into the substrate using nano-fabrication techniques, such as hydrogen lithography provided by scanning-tunnelling-microscopes, or industry-standard ion implantation techniques. In some examples, the donor atom 108 may be a phosphorus atom in a silicon substrate and the quantum dot 100 may be referred to as a Si:P quantum dot. In the example depicted in FIG. 1, quantum dot 100 includes a single donor atom 108 embedded in the silicon-28 crystal. In other examples, the quantum dot may include multiple donor atoms embedded in close proximity to each other.

Gates 112 and 114 may be used to tune the electron filing on the quantum dot 100. For example, an electron 110 may be loaded onto the quantum dot 100 by a gate electrode, e.g., 112. The physical state of the electron 110 is described by a wave function 116—which is defined as the probability amplitude of finding an electron in a certain position. Donor qubits in silicon rely on using the potential well naturally formed by the donor atom nucleus to bind the electron spin.

FIG. 1B shows another example semiconductor quantum dot 150 that can be implemented in the quantum accelerator of the present disclosure. This is similar to the quantum dot 100 shown in FIG. 1A, a difference being the placement of the gates. In FIG. 1A, the gates 112, 114 were placed on top of the dielectric 104. In this example, the gate 152 is located within the semiconductor substrate 102. In some embodiments, the gate 152 is placed in the same plane as the donor dot 108. In other embodiments, the gate 152 may be placed in a different plane. Such in-plane gates may be connected to the surface of the substrate via metal vias (not shown). Voltages may be applied to gate electrode 152 to confine one or more electrons 110 in the Coulomb potential of the donor atom 108.

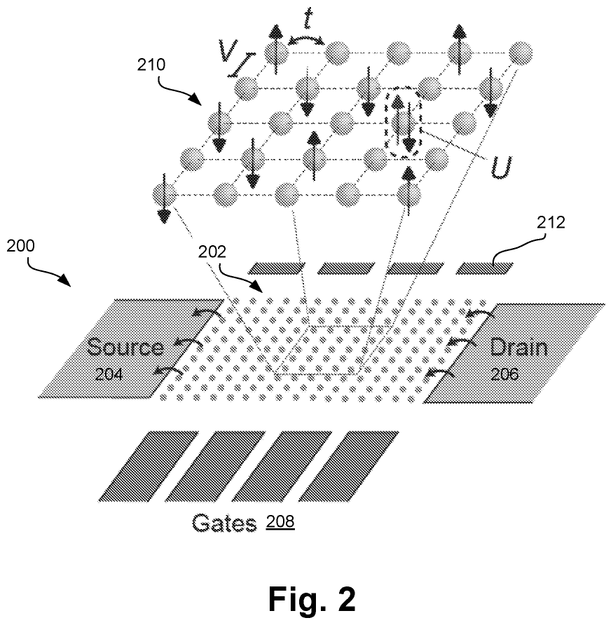

FIG. 2 shows an example AQS 200 according to aspects of the present disclosure. The AQS 200 comprises a donor quantum dot array 202, a source 204, a drain 206 and a plurality of control gate electrodes 208. In one example, the quantum dot array 202 comprises an array of donor quantum dots, where each quantum dot is similar to that shown in FIG. 1A or FIG. 1B. The inset 210 in FIG. 2 shows a zoomed in view of a 5x5 section of the quantum dot array 202. As seen in the inset, the quantum dots are arranged in a square lattice. Each of the circles in the inset represents a quantum dot, and the arrows in the quantum dots represent electrons coupled to donor atoms of the quantum dots-in either a spin-up or spin-down state.

The inset 210 also shows some parameters of the extended Hubbard Hamiltonian (i.e., the underlying mathematical description) that describes the behaviour of electrons in the quantum dot array 202. In particular, inset 210 shows the long-range electron-electron interactions (V) between two quantum dots, on-site Coulomb interactions (U) between a pair of electrons on a single quantum dot, and nearest neighbour electron transport (t) between two adjacent quantum dots. The Hamiltonian in equation 1 describes this system.

The AQS 200 can be used to encode simulation and optimization problems by controlling the on-site interactions U, the inter-site interactions V, tunnel coupling t and electrochemical potential μ.

FIG. 2 shows a square 2D structure of the quantum dot array 202. This square array quantum dot array 202 design can be used for simulation of low-dimensional materials such as copper-oxide planes in high-temperature superconductivity. However, it will be appreciated that the quantum dot array 202 need not be a square 2D structure. Instead, the quantum dots may be positioned in the array 202 in other formations/structures.

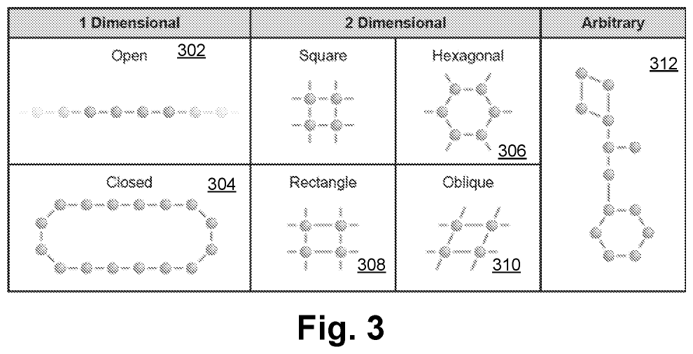

FIG. 3 depicts some example quantum dot array structures, such as a ID open array 302 consisting of tunnel coupled quantum dots with open boundary conditions or a 1D closed array 304 with closed boundary conditions that can be used to investigate periodic Hamiltonians for computation problems such as quantum rings and 1D crystals. Further, the quantum dots may be structured in a number of other 2D structures for solving complicated optimization or simulation problems. Such structures include a 2D hexagonal array 306, a 2D rectangular array 308, or a 2D oblique array 310. In other examples, the array may have a completely arbitrary structure 312 that can also be used for complex optimization problems. Further, the number of quantum dots 100 present in the array 202 may vary depending on the particular implementation.

Although a single source 204 and a single drain 206 are shown in this example (FIG. 2), this need not be the case always. In other embodiments, the AQS 200 may include a plurality of drain and/or source leads. Further, the number of control gates 208 utilized in the AQSs 200 may vary.

Further still, the quantum dot array 202 can be fabricated in 1D or 2D where the input gate electrodes 208 are in-plane with the array 202 (as shown in FIG. 1B) and/or in 3D where the gates 208 can be patterned on a second layer after overgrowing the quantum dot array layer with epitaxial silicon. The ultra-low gate density of Si:P quantum dots allows for the fabrication of large quantum dot arrays with few control electrodes.

The quantum dot array 202 is weakly coupled to the source 204 and drain 206 to measure the electron transport through the quantum dot array 202. Further, the quantum dot array 202 is capacitively coupled to the plurality of control gates 208. The control gates 208 can be used to tune the electron filling, inter-dot couplings and the single-particle energy levels of the quantum dot array 202.

In addition to the source, drain and control gates, the AQS 200 may further include one or more sensors in some embodiments. For example, an individual gate electrode 208 may be used as a sensor. Alternatively, a sensor 212 may be s single electron transistor SET, or a single lead quantum dot (SLQD) The sensors may be configured to perform spin readout. In some examples, the sensors may be separate charge sensors and in other examples, two or more control gates 208 may be used to dispersively sense the charge of qubits. The charge sensors can be implemented with various structures. Examples of charge sensors that could be used are: a single electron transistor (SET), a single electron box (SEB), and a tunnel junction. The use of dedicated charge sensors allows for direct spin readout. However, dispersive readout using nearby gates 208 reduces the device complexity and instead measures the charge state of the qubit.

Although FIGS. 1-2 depict surface or in-plane gates, this need not be the case always. By using in-plane gates, the number of gates required to control the qubits in a given quantum dot array can be reduced when compared to surface gates. However, in some examples, the AQS 200 may include global control, e.g., by use of a loop-gap resonator or microwave resonator that can be placed in proximity to the quantum dot array 202 to direct the required magnetic field to control the qubits of the AQS 200.

### Fabrication the AOS

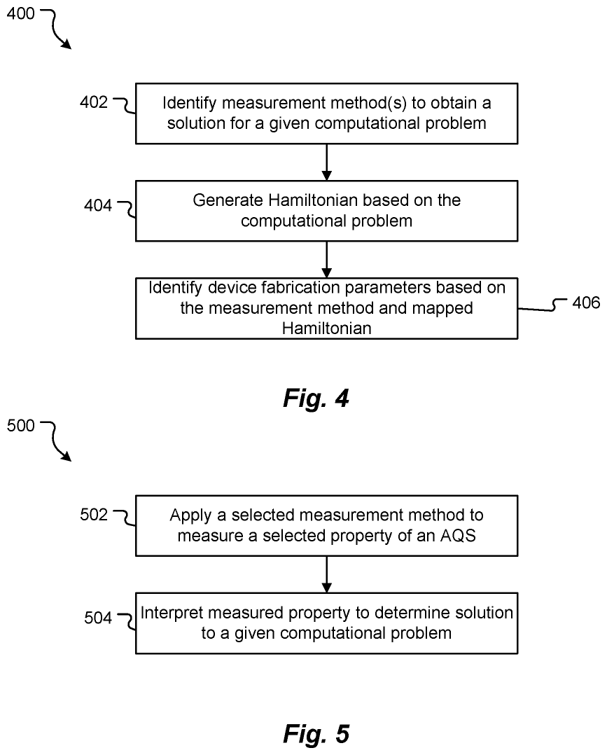

FIG. 4 is a flowchart illustrating an example method 400 for determining fabrication parameters for an AQS 200 according to aspects of the present disclosure.

The method 400 commences at step 402 where one or more measurement methods to obtain a solution based on a given computational problem that needs to be solved are identified. The measurement methods are determined by the nature of the problem. For example, based on a given computation problem such as a quadratic continuous optimization problem, it may be determined that the solution of the problem lies in measuring the ground state energy of a quantum dot array 202 of an AQS 200 and in measuring the current through the quantum dot array 202. In another example, it may be determined that the solution of a computational problem can be determined by measuring the electron transmission probability of the quantum dot array 202, measuring a voltage and/or capacitance using a four-point probe measurement, or measuring the electron occupation of qubits in the quantum dot array 202.

Next, at step 404, the selected computation problem is mapped onto the Hubbard Hamiltonian. This step may be considered ‘encoding’ the computational problem to the Hubbard Hamiltonian. The universality of the Hubbard model allows for any computational problem to be mapped to the Hubbard Hamiltonian (i.e., the underlying mathematical description). For example, if the computational problem is a chemistry simulation then the problem will have a Hamiltonian associated with it. Some chemistry simulation problems (such as simulating the SSH model) may be mapped directly to the Hubbard model to determine the Hamiltonian for the problem. Other chemistry simulation examples may require a more involved transformation to the Hubbard model to determine the Hamiltonian for the problem. Mapping the computational problem to the Hubbard Hamiltonian may encode the output of any quantum computation in its ground state (or its dynamics). For example, many optimisation problems can be mapped directly to a Hubbard Hamiltonian such that the occupation number of the sites is the solution to the problem.

By way of example, if a device is fabricated such that Uᵢ>Vᵢⱼ>>tᵢⱼ, ∀i, j, the electrons preferentially fill the whole quantum dot array before filling the same quantum dot. In this limit the electron hopping term (t) can be neglected as it is much smaller in energy than the other terms in the Hamiltonian, thus and the Hubbard Hamiltonian becomes the quadratic unconstrained binary optimisation (QUBO) Hamiltonian:

$${H}_{Q U B O} = {\sum }_{i < j} {V}_{i j} {n}_{i} {n}_{j} - {\sum }_{i} {μ}_{i} {n}_{i} \qquad ( 2 )$$

The distances and sizes of the quantum dots in the AQS 200 are then chosen to replicate the parameters of this QUBO Hamiltonian and the device is constructed in this way then measured.

Alternatively, if the device is constructed such that Uᵢ>tᵢⱼ>Vᵢⱼ, ∀i, j, then the inter-site interaction may be neglected as the remaining terms in the Hamiltonian dominate. Therefore, the Hubbard Hamiltonian is reduced to the XY Hamiltonian:

$${H}_{Q C O} = - {\sum }_{i} {μ}_{i} \frac{‖ - {σ}_{i}^{z}}{2} + {\sum }_{< i , j >} {t}_{i , j} \frac{{σ}_{i}^{x} {σ}_{j}^{x} + {σ}_{i}^{y} {σ}_{j}^{y}}{4} \qquad ( 3 )$$

In such cases, the occupation of a quantum dot is either 0 or 1 because the cost of adding more than 1 electron to a dot is greater than filling the rest of the quantum dot array with 1 electron. Therefore the occupation can be interpreted as a spin half particle, with |0 [symbol] =|↓ [symbol] and |1 [symbol] =∥↑ [symbol] . From this, a transformation of the creation and annihilation (a^{†} and a) can be made as follow:

$${c}_{j} = \frac{{ω}_{x}^{j} + i {ω}_{y}^{j}}{2} \qquad ( 4 )$$

$${c}_{j}^{†} = \frac{{ω}_{x}^{j} - i {ω}_{y}^{j}}{2} \qquad ( 5 )$$

$${n}_{j} = {c}_{j}^{†} {c}_{j} = \frac{1 - {ω}_{z}^{j}}{2} \qquad ( 6 )$$

and the determined Hamiltonian follows.

This model can be used to solve QCO (quadratic continuous optimisation) problems. In the regime where Vᵢⱼ≈tᵢⱼ (i.e., they are similar in magnitude), both Vᵢⱼ and tᵢⱼ must remain in the Hamiltonian. As such, more complex hybrid problems such as an MBO problem (mixed binary optimisation problem) may be solved. This can be used for optimisation problems with both binary and continuous variables, or to introduce constraints unavailable in QUBOs, e.g. inequality constraints. One particular example of an MBO problem may be a transaction settlement problem.

Finally, if U is not large enough, the Hamiltonian describes an n-vector model which can again be used for more complex optimisation tasks. In this regime it is not necessarily energetically favourable for the whole quantum dot array 202 to be filled before a single dot gains more than one electron. This means the problem is no longer binary and the ground state will represent some more complex problem with more complex interactions.

At step 406, fabrication parameters for the device can be determined based on the selected measurement technique and based on the parameters of the Hamiltonian determined at step 404 by the mapping.

Accordingly, once the Hamiltonian has been determined for a problem, the quantum dots 100, 150 of an AQS 200 are placed so that the Hamiltonian these dots experience is a determined Hamiltonian. This is achieved by arranging the quantum dots so that the distances between them correspond to the coupling strength and their size(s) and/or orientation(s) induces the appropriate Coulomb interactions.

For example, if the computational problem was directed to investigating the presence of superconductivity in the CuO plane of cuprate systems, the relevant measurement method would need to provide information of the global superconducting phase of a 2D array. Therefore, the measurement method relevant for this computational problem may be “Hall bar” like measurements since this allows global properties of large arrays to be accessed. It will be appreciated that the Hall bar is a specific implementation of a four-point probe measurement.

The number, size, and placement of the quantum dots are chosen to simulate the CuO planes in cuprate systems. In particular, superconductivity has been predicted in the single-band Hubbard model in the intermediate coupling regime with U/t˜5. This sets the size and spacing of the quantum dots. The quantum dot array should mimic the CuO lattice, therefore the quantum dots should be arranged in a square lattice. The number of quantum dots is arbitrary, but in general, the larger the array the less prone to disorder/edge effects it is.

The selected measurement technique may determine the number and geometry of the source 204, drain 206, gates 208 and sensors 212. For example, if the selected measurement technique is measuring the electron occupation of qubits in the quantum dot array 202 it may be determined that one or more sensors are required to measure the electron occupation. Alternatively, if the selected measurement technique is measuring the ground state energy of the array 202 it may be determined that no sensors are required in the AQS. Further, the selected measurement technique may determine the number and geometry of the fabrication planes for the gates 208, quantum dot array 202 and sensors 212. That is, the selected measurement technique may dictate the number of fabrication planes required (e.g., one, two or three), and the geometry of the planes (e.g., gates on one plane, the quantum dot array 202 on the same plane or a different plane and the sensors 212 on the same or different plane). For example, if the selected measurement technique is measuring the Hall Effect, multiple planes may be required. Similarly, for electron transmission measurements, one or more source lead and one or more drain lead connections may be required at specific locations around the quantum dot array 202.

The Hamiltonian determined from mapping the computational problem to the Hubbard Hamiltonian (see equation 1) on the other hand may dictate the size and shape of the quantum dots and the quantum dot array, the distance between adjacent quantum dots in the array 202, the magnetic field to be applied to the AQS 200, the detuning (i.e., the electrochemical term in the Hamiltonian μᵢnᵢ) to be applied to the quantum dots, and/or the number of dots required. For example, the on-site energy, U, of the Hubbard Hamiltonian can be varied from 1-100 meV by changing the size of the quantum dots in the AQS from having a single donor atom to having 100 donor atoms (i.e., from 1P to ˜100P donors). The tunnel coupling parameter, t, can be varied from 0.001-10 meV and the inter-site energy, V, can be varied from 0.01-20 meV by changing the inter-dot separation/geometry of the quantum dots from 5-100 nanometers in the array 202. The chemical potential of the Hubbard Hamiltonian can be varied by changing single-particle energy levels of the order of 100 meV over multiple bands. Further, the temperature of the array can be varied from 0.001 to ˜4 me V by operating the dilution refrigerator at different temperatures from 10 mK to 50 K.

Once the fabrication parameters for the AQS 200 are determined, the AQS can be fabricated based on the determined parameters.

It will be appreciated that in some embodiments method 400 is implemented by a classical computer. For instance, the classical computer includes a memory that stores instructions for performing steps 402-406 and a processor that is configured to execute the stored instructions. In some examples, the classical computer communicatively coupled to one or more client devices via a communication network such as the Internet. Users of the one or more client devices may provide a computation problem such as a simulation or optimization problem to the remote computer via the client devices. The remote computer may receive the user input and based on the computational problem selected by the user(s) perform steps 402-406 to determine the fabrication parameters to build an AQS 200 to solve the provided computation problem.

### Example Method for Solving A Computation Problem Using a Fabrication AOS

Once an AQS 200 is fabricated to solve a computational problem, e.g., using method 400, the AQS 200 can be used to solve the computational problem. FIG. 5 is a flowchart illustrating an example method 500 for using an AQS according to aspects of the present disclosure. The method 500 commences at step 502 where the AQS 200 is setup and the selected measurement technique is applied to measure the selected property of the AQS.

At step 504, the measured results are interpreted to determine the solution to the computational problem.

The different methods to extract information from the quantum dot array 202 are summarized in Table. A below.

TABLE A
Measurement methods, their respective information,
what problems they are suitable for.

| Method | Information | Problem(s) |
|---|---|---|
| Ground state energy | E(<n>) | Simulation, optimization |
| Electron transport | Γ(<n>) | Simulation, optimization |
| Voltage and/or | Global state | Simulation |
| capacitance using a | | |
| four-point probe | | |
| measurement | | |
| Electron occupation | nᵢ | Simulation, optimization |

For instance ground state energy may be used as a measurement technique for an optimisation problem where only the cost of a solution is required (e.g. in risk analysis for insurance, the exact circumstances causing a particular damage may not matter, and only the cost of the damage may be important). In a second example, ground state energy may be used as a measurement technique for a chemistry simulation problem where some physical variable is desired e.g. bond length, ground energy, reaction rate of a molecule.

Electron occupation on the other hand may be used as a measurement technique for optimisation problems where the solution is desired. For example, it may be used in a travelling salesman problem where the optimal route of travel is required. Further, electron transport may be used as a measurement technique for simulation problems related to energy transfer in organic conductors.

Finally, four-point probe measurements may be adopted to measure a voltage and/or capacitance for problems that are related to simulating condensed matter phases such as superconductivity. The Hall effect measurement is a specific example of the more general four-point probe measurement.

Based on the desired feature to be extracted from the device there are different methods to determine the solution to the problem. For example, if one is only interested in the overall energy of the ground state then the transport properties of the device can be measured to determine the addition energy of the total array.

The different methods can be used for various problems as summarized in Table A. The most general form of analogue quantum computing relies on measuring the charge occupation of the quantum dots. By encoding different problems into the Hamiltonian different quantum computations can be performed on a quantum dot array. Depending on the encoded problem the interpretation of the measured results can lead to different information. For example, if the ground state encodes the solution to an optimization problem, it can be determined what the cost of the solution is not the exact state. This may be useful for certain risk analyses where the exact solution is not needed but the expected risk is required.

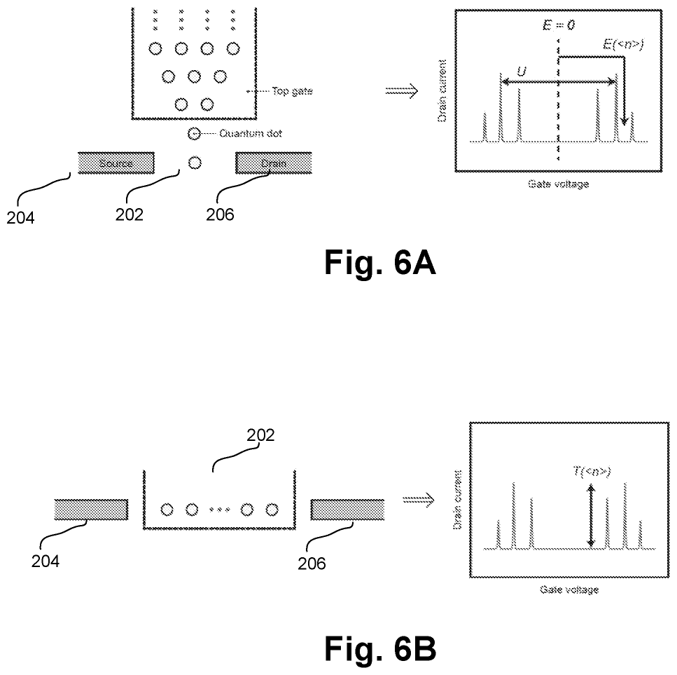

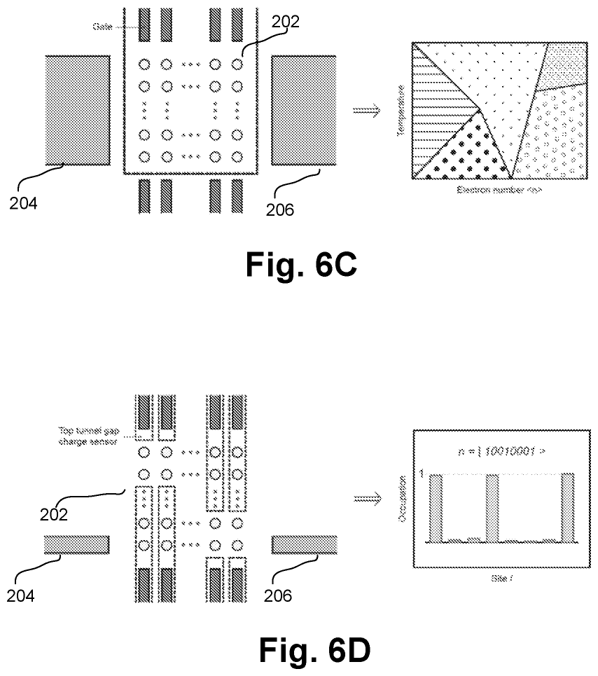

FIG. 6 is a schematic showing different measurement techniques applied to different analog quantum systems to measure selected properties of the AQS. The measurement method may limit the array structure geometries available that can be simulated. In particular, FIG. 6A depicts an AQS device 200 having a ID quantum dot array 202. Also, shows are a source lead 204 and a drain lead 206. This device is used to determine the ground state energy of the quantum dots in the array 202, E( [symbol] n [symbol] ). In this case, a voltage is applied to the one or more control gates of the AQS 200 and the drain current is measured. The current through the quantum dot array can be used to determine when an electron is loaded onto the array. By ensuring that U is the largest interaction, the start of an orbital can be reliably defined to begin with 0 electrons.

Conduction peaks may then be charted based on the applied voltage and measured drain current readings. By tuning the gate voltages and measuring the energy gaps between the conductance peaks the energy required to obtain that electron number solution can be estimated. That is, the solution to the problem to be solved can be estimated.

FIG. 6B depicts an AQS device (with a ID quantum dot array) that is used to measure electron transmission, T( [symbol] n [symbol] ). By connecting the source 204 and drain leads 206 to various positions in the quantum dot array 202, the transport dynamics across various quantum dot sites can be examined. The transport dynamics may be engineered in the AQS device and different geometries can be used to examine different properties (preferential transport, etc). For example, by connecting the source and/or drain to a section of the quantum dot array 202 where energy transfer occurs, the efficiency of the electron movement can be studied. In particular, as with FIG. 6A, in this case, a voltage is applied to the one or more control gates of the AQS 200 and the drain current is measured. Conduction peaks may then be charted based on the applied voltage and measured drain current readings. Thereafter, the solution to the computational problem may be determined by measuring the height of the conductance peaks where the higher peaks correspond to better electron transmission.

FIG. 6C depicts an AQS device (with a 2D quantum dot array) that is used to measure Hall Effects. For low-dimensional materials (such as 2D materials), the conductance and electron densities can be tuned for a variety of applications. To investigate the properties of such two-dimensional materials, Hall measurements can be performed on an AQS 200 (having similar dimensionality to the low-dimensional material) to elucidate various fundamental and critical phases. In some examples, a four-probe measurement may be used to measure a voltage and/or capacitance from a quantum dot array of the AQS. In some examples, atomic Hall bars may be implemented for investigation of fundamental physics and designing/simulating new 2D materials for a wide range of applications. By varying the experimental parameters such as temperature and doping density of the quantum dot array 202, the full phase space of different arrays can be measured.

FIG. 6D depicts an AQS device (with a 2D quantum dot array and charge sensors 212 fabricated on a separate plane) that is used to measure the electron occupation of each site in the 2D quantum dot array. This arrangement can be used to obtain binary solutions to computational problems. By measuring multiple charge sensors 212 simultaneously it is possible to triangulate the different quantum dots 100, 150 in the array 202 and determine when an electron occupies a given site. It will be appreciated this may be used on quantum dot arrays with any number of electrons on the quantum dot. This can be used to perform general quantum computation. Further, by using charge sensors to calibrate the location of the electron occupation, the output of a particular computation can be determined. It is also possible to design a 3-layer device where the bottom layer is a large electrode used to shift the global potential of all the quantum dots. The quantum dot is then patterned followed by the charge sensor layer on the top.

This is extremely powerful and allows for computation of optimization problems as well as universal quantum computation provided the Hamiltonian of the system is tuned correctly.

In some examples, before the AQS 200 can be used, it is initialized. Initialization of the AQS 200 requires cooling it down in a dilution refrigerator. The colder the AQS 200, the better the resolution of the charge configurations and hence accuracy in the solution to the problem.

### Simulating the SSH Model Using Method 400 and Method 500

In the previous section example methods 400 and 500 were explained in general terms. For clarity, the methods 400 and 500 will be explained using a particular example.

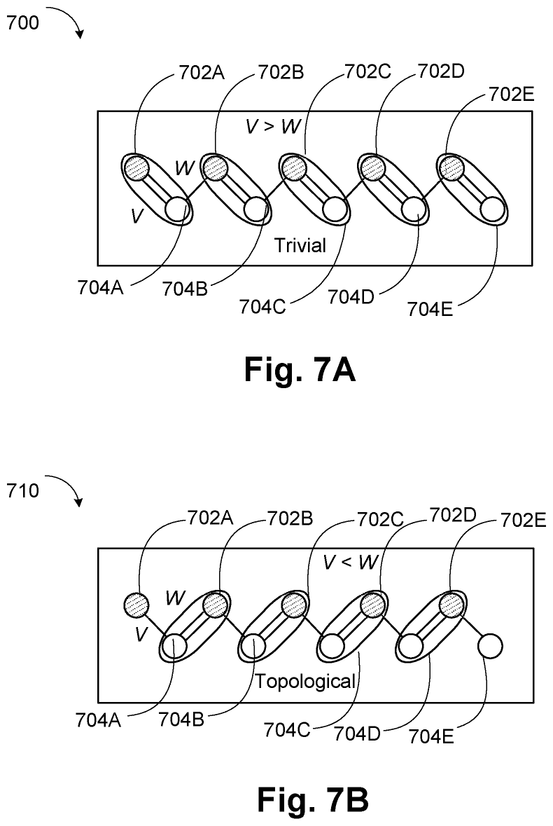

In one example, the computational problem may be simulating the Su-Schrieffer-Heeger (SSH) model. The SSH model is one of the simplest known instances of topological quantum systems and describes a single electron hopping along a one-dimensional (1D) dimerised lattice with staggered tunnel couplings, v and w as shown schematically in FIGS. 7A and 7B. The dimerised one-dimensional lattice arises because there are two hopping energies v, w. FIG. 7A shows a ID quantum dot array 700 in the trivial phase comprising 10 quantum dots (702 and 704) with staggered tunnel coupling v>w. FIG. 7B shows a 1D quantum dot array 710 in the topological phase comprised of 10 quantum dots (702 and 704). In the topological non-trivial phase the staggered tunnel coupling take the form of v<w.

At step 402 of method 400 the measurement method is identified. The eigenenergies of the SSH model give rise to two distinct phases: a topologically trivial phase (FIG. 7A) where the system is a bulk insulator (and v>w); and a topologically non-trivial phase (FIG. 7B) (where v<w) which gives rise to two zero-energy edge states where the electron is localized at the two boundaries of the 1D lattice. Therefore, it may be readily concluded that one of the appropriate measurement methods for the computational problem of simulating the SSH model is measuring the ground state energies. Further, it could be concluded because of the 1D nature of the SSH model that a four-probe measurement or Hall Effect would not be a desirable measurement method for this problem.

Next at step 404, the computational problem of simulating the SSH model is mapped to the general Hubbard Hamiltonian of equation 1. In some examples the SSH model may be a non-interacting model, where both the intra-and inter-site electron interaction energies can be set to zero and the chemical potential is also set to zero. In other examples, the SSH model may be interacting and have non-zero Coulomb potential and/or chemical potential. The SSH model requires that the electron hopping terms have alternating strengths in order to observe the topological phases while being simultaneously large enough for measurable transport current for bias spectroscopy.

Thus the final Hamiltonian generated when mapping the interacting SSH model to the Hubbard Hamiltonian is given by:

$${H}_{S S H} = {\sum }_{i} {U}_{i} {n}_{i} ( {n}_{i} - 1 ) - {\sum }_{i} {μ}_{i} {n}_{i} + {\sum }_{i < j} {V}_{i j} {n}_{i} {n}_{j} + {\sum }_{n = 1}^{N} {v}_{n} {c}_{n , 1 {c}_{n , 2}}^{†} + {w}_{n} {c}_{n , 2}^{†} {c}_{n + 1 , 1} + h c \qquad ( 7 )$$

Where vₙ=v, ∀n and wₙ=W, ∀n.

Next at step 406 of the method, the device fabrication parameters are identified based on the measurement method and the mapped Hamiltonian. Because it is desirable to measure the ground state energy of the topologically trivial and topologically non-trivial states, two AQS devices will be required to simulate the SSH model.

As described above, the measurement methods identified were 1) the ground state energy measurement and 2) electron transport of the SSH model. As such, a source and drain lead were required to measure current across the quantum dot array and no charge sensors are required.

Based on the determined SSH Hamiltonian, an even number of quantum dots are required for symmetry purposes. Ten quantum dots is at the limit of what is classically able to be simulated. Thus 10 quantum dots were chosen so as to compare the theoretical results with the measured results. The geometry of the quantum dot array was determined by the requirement of the SSH Hamiltonian to have alternating tunnel interaction strengths along a 1D chain (for example, similar to the open quantum dot array 302 shown in FIG. 3). In this example, electrostatic modelling was performed to determine the minimal number of gates that was able to control the array of quantum dots. Accordingly, it was determined that at least six gates were required and that these gates could be placed in plane with the quantum dot array.

The inter-dot separation distances were determined such that a measurable current could be measured but small enough that the dots were independent (v, w˜1 meV<U˜25 meV).

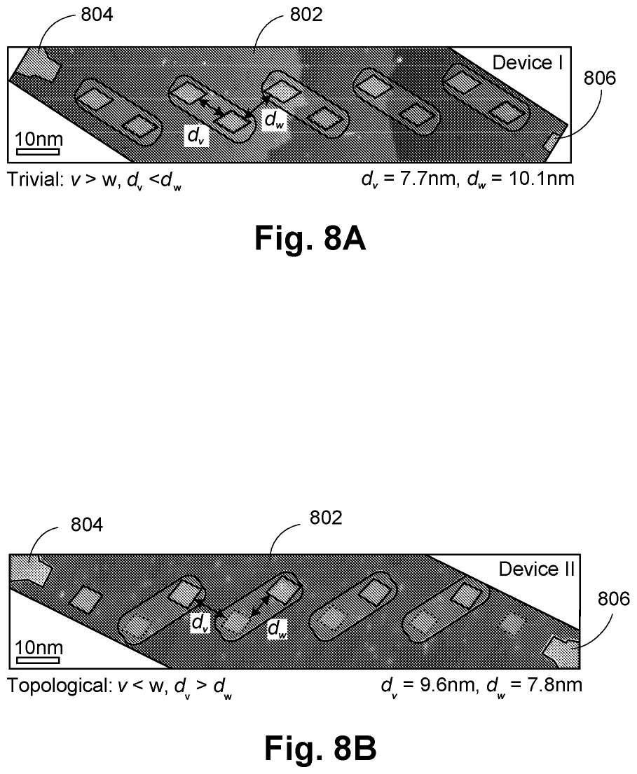

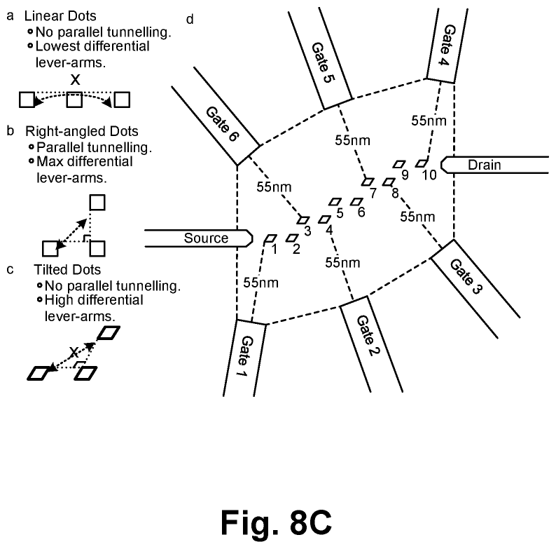

After method 400 is performed two AQS devices are fabricated using the identified device fabrication parameters—see FIGS. 8A and 8B. Device I is fabricated to model the topologically trivial phase and Device II is fabricated to model the topologically non-trivial state. Both Device I and Device II are example AQSs. In the devices shown in FIGS. 8A and 8B, the quantum dot array 802 is tunnel coupled to the source 804 and drain leads 806 in order to perform bias spectroscopy through the array 802. The regions outlined in orange and blue represent the quantum dots in the different sub-lattices of the SSH model. The tunnel couplings t_{i,i+1} are engineered via the inter-dot donor separation, d_{i,i+1} and follows an inverse exponential dependence,

$${t}_{i , i + 1} ∝ exp ( - \frac{2 {d}_{i , i + 1}}{3} ) .$$

Non-nearest neighbour tunnelling is exponentially suppressed with estimated t_{i,i+2}/t_{i,i+1}≈0.01, ensuring electron transport occurs in series through the chain. The SSH model requires that the tunnel couplings are alternating strengths to observe the different topological phases while simultaneously being large enough to allow for a measurable transport current for bias spectroscopy. The quantum dot size is then critical as the confinement potential experienced by the outer electron and hence the wavefunction overlap of the neighbouring quantum dot depends on the number of donors comprising the quantum dot. As such, to achieve uniformly staggered v and w the inter-dot separation and quantum dot size must be engineered with nanometre precision. The quantum dots are fabricated with an area of ˜25 nm² (˜25 P donors per site) separated by 7-11 nm (t≈1-10 meV) where a small difference in donor number will not dramatically change t, U, or V. Example device shown in FIG. 8A is designed to be in the trivial configuration with average staggered quantum dot distances, dᵥ=7.7±0.1 nm and d_{w}=10.1±0.2 nm corresponding [symbol] v/w [symbol] =2.08. In the example device shown in FIG. 8B is designed to be in the topological non-trivial phase with average staggered donor distances are dᵥ=9.6±0.4 nm and d_{w}=7.8±0.6 nm corresponding to [symbol] v/w [symbol] =0.265.

The SSH chain requires alternating nearest-neighbour tunnel couplings, which are engineered via the inter-dot donor separation and follows an exponential dependence. Along with the alternating tunnel couplings, the inter-dot donor separation also needs to be close enough that there is sufficient transport current through the device, at low SD bias, such that we can measure current through the chain, while the donor dots also need to be far enough away, in order to prevent the tunnel and capacitive couplings between the donor dots being too large, such that the dots behave independently from each other.

As the donor dot sizes for the devices in this disclosure are restricted to donor dot separations around 6≤dᵢ≤12 nm. Within this range the donor dots are spaced far enough away such that they behave independently, close enough that sufficient current can be measured through the device, while allowing a large enough ratio between the alternating tunnel couplings, due to the exponential dependence, to be far enough within the trivial and topological regimes of the SSH model.

The quantum dot (QD) sizes in the devices are ≈25 nm² hosting ≈25 P donors per site. These sizes were chosen as they allow for uniform quantum dots that are robust against variations in a few P donors, whereas for small quantum dot sizes of a few P donors, a change in a single P number results in non-uniformity with large variations in Uᵢ and Vᵢⱼ. Conversely, for large quantum dots the capacitive coupling between the dots become too large, resulting in the dots not behaving independently, in which case the separations between the dots would need to be increased to accommodate this. In this example, the onsite Coulomb energy is U≈25 meV and the inter-site Coulomb energy is V<5 meV. And the temperature is T≈100 mK.

To be able to tune the chemical potential of the quantum dots in the chain requires control gates capacitively coupled to the quantum dots. In order to tune the chemical potentials of each quantum dot independently, such that all possible energy level combinations across the 10 dot chain could be accessed, would require at least 10 control gates. However, for realising the SSH model across the chain this is not necessary, as it is only required to be able to bring the chemical potentials into resonance, at zero source/drain bias.

Due to physical restriction on the size of the chain, determined via the quantum dot sizes and separations, it is infeasible to fit 10 control gates into the device, while still having the gates separated far enough away to allow reasonable operating gate ranges before breakdown leakage occurs. Also, more gates doesn't necessarily allow more independent control in tuning the chemical potentials of individual dots, if the gates are equally capacitively coupled to the same quantum dots. What is more important is to have sufficient differential lever-arms between the gates to the quantum dots. Where differential lever arms refers to the ability to the change the electrochemical potential of the quantum dots relative to each other. Absolute lever arms refers to the ability to tune the electrochemical potentials of the quantum dots together.

In order to maximise the absolute and differential lever-arms, the layout of the 10 dot chain and the gates were considered. FIG. 8C shows a schematic of a segment of the chain with the dots in a linear, right-angled and tilted arrangement respectively. The linear arrangement results in the lowest differential lever-arms and the independent control of the dots is greatly reduced. To improve this the dots can be arranged in a tilted array, with maximal control occurring when the dots are arranged at right angles. However, in the right-angled arrangement the next-nearest neighbour distance between the dots is reduced resulting in the next-nearest neighbour tunnel couplings comparable to the nearest-neighbour tunnel couplings. This allows for parallel tunnelling through the dots, which is not allowed in the SSH model, which requires sequential tunnelling through the chain.

As such, in order to prevent parallel tunnelling through the chain, while still maximising the differential lever-arms, the dots were arranged in a tilted array with a 120° angle. In this arrangement next-nearest neighbour tunnelling is exponentially suppressed with estimated t_{i,i+2}/t_{i,i+1}≈0.01 ensuring electron transport occurs sequentially through the chain.

Once an AQS 200 is fabricated to simulate the SSH model, e.g., using method 400, the AQS 200 can be used to simulate the computational problem using method 500.

At step 502, a current is applied to fabricated Device I to measure the conductance—here the identified measurement method from step 402 was measuring the ground state. Similarly, a current is applied to Device II to measure the conductance.

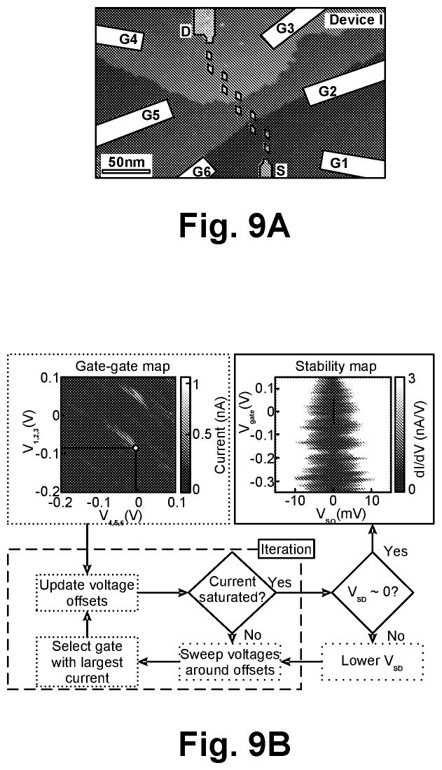

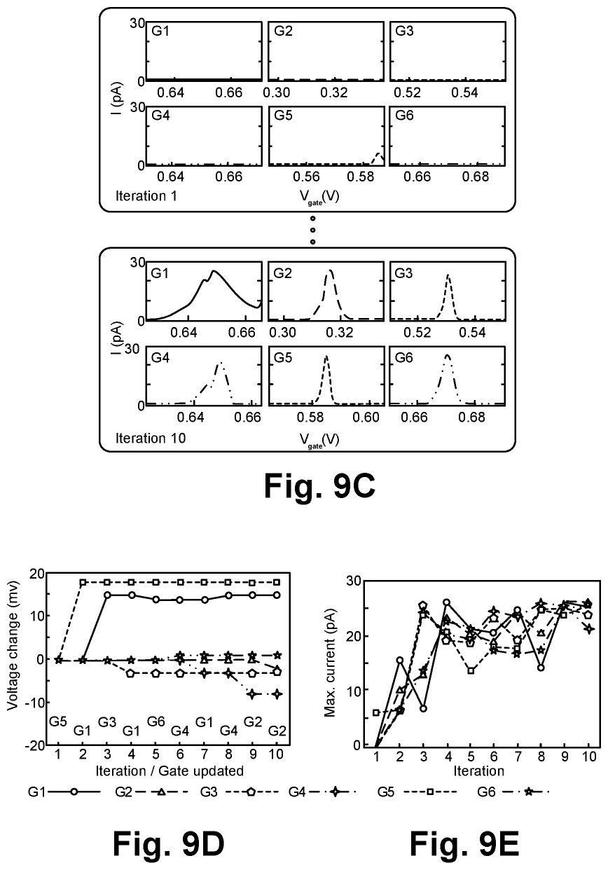

FIG. 9A shows an STM image of the full Device I. Here, the outlined lighter regions show the lithographic hydrogen mask with 6 capacitively coupled control gates (G1 to G6), crucial to independently control the electrochemical potentials of the quantum dots Device II is substantially similar with respect to the number of gates. Due to the unique geometry of the device the total lever-arms of all gates linked together to each quantum dot are engineered to be consistent with a variation of <2.5%. This small variation means that the global electrochemical potential of the whole quantum dot array can be raised for bias spectroscopy to measure the different phases of the SSH model. To align the electrochemical potentials of the quantum dots, a maximum current alignment scheme was used, in which the individual gates are tuned as outlined in FIG. 9B.

This is achieved by initially setting the gate voltages at a conductance peak determined by sweeping G1, G2, and G3, against G4, G5, and G6, while measuring the current through the array. While positioned at this conductance peak each gate is then individually swept around a set value, while all other gates were kept constant, as illustrated in FIG. 9C.

After sweeping all six gates about their set voltage, the largest current peak is found and the corresponding gate is updated to the voltage at the centre of the current peak (G5 in the first iteration shown in FIG. 9D). All gates are then swept again, repeating this process, updating a single gate at a time as shown in FIG. 9D.

FIG. 9E shows the maximum current measured on each gate sweep per iteration for a constant source/drain bias, V_{SD}. When the maximum current plateaus, V_{SD} is reduced further and the entire process is repeated to increase the alignment accuracy.

Once the electrochemical potential of the quantum dots are aligned, we perform a stability diagram measurement by shifting the electrochemical potential of all quantum dots to investigate the electron occupation of the array. The stability diagram allows us to determine the electron occupation of the array as a function of the electrochemical potential of the quantum dots. At zero source-drain bias (dashed white line in FIG. 9B) there is only enough energy to add a single electron to the array at a time. In this regime the SSH model is simulated.

Next, at step 504 the measured data-the conductance peaks-are interpreted (analyzed) to determine the solution to the SSH model.

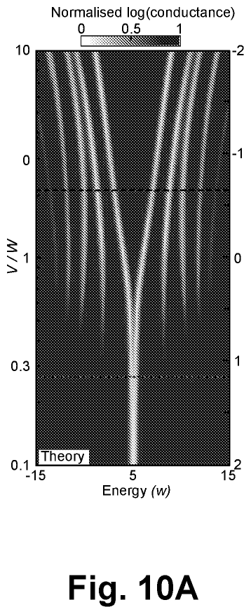

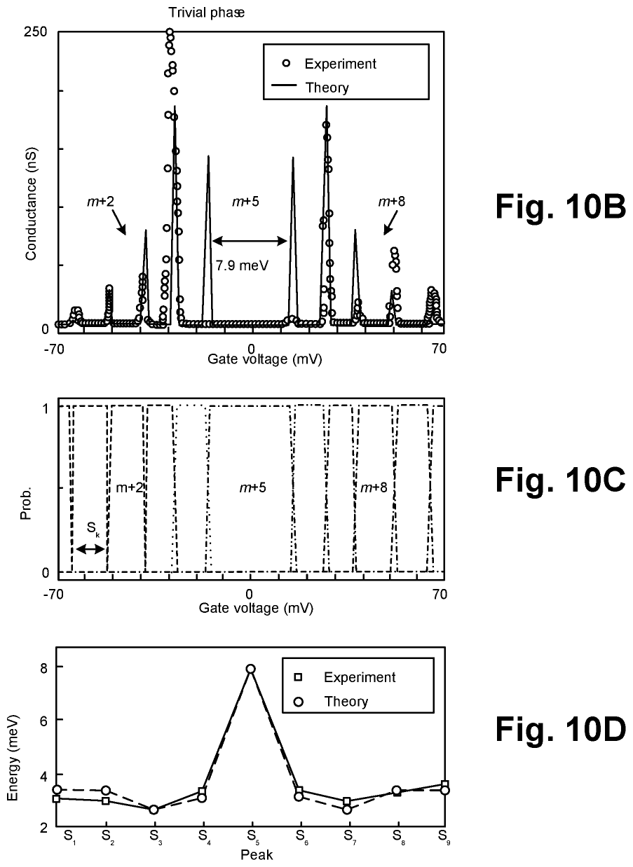

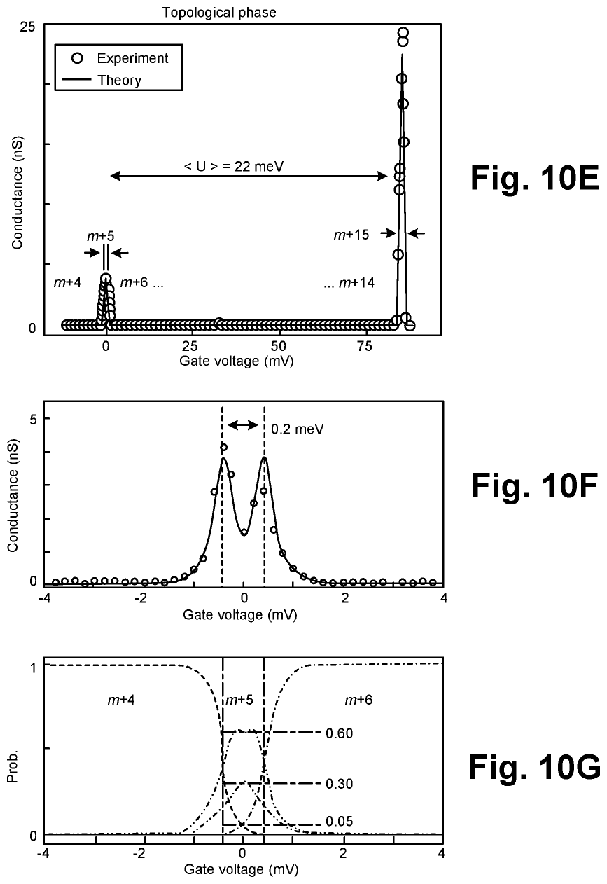

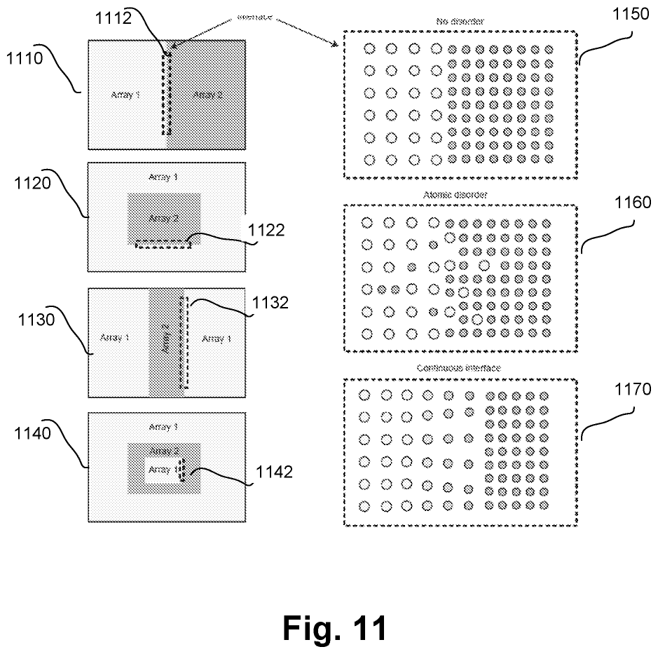

FIG. 10 shows a comparison of the experimental and theoretical results of Device I and Device II.

FIG. 10A shows the calculated normalised zero-bias conductance as a function of the ratio of tunnel couplings (v/w) of the array. The design of Device I in the trivial phase is given by the dashed red line ( [symbol] v/w [symbol] =2.08) while Device II in the topological phase is given by the dashed blue line ( [symbol] v/w [symbol] =0.265).

FIG. 10B shows the zero-bias conductance as a function of the combined voltages on all the gates obtained from the trivial phase (Device I) with the theoretical calculation shown in red. There are ten conductance peaks corresponding to a change in the total number of electrons on the array, see FIG. 10C. The electron filling of the array is controlled by adjusting the gate voltages to tune the electron number from m to m+10 (half-filling). At a quarter-filling (m+5) there is a gap in the energy spectrum 7.9 meV corresponding to the single ground state of the SSH model for the trivial phase.

From the estimate of V_{i,j} from electrostatic modelling, and fitting the magnitude of the tunnel coupling, we model the array to obtain the width of the different electron number regions, Sₖ (width of the m+k→m+k+1 region). FIG. 10D shows the width of the experimentally measured stability regions, obtained by determining the energy between adjacent conductance peaks, compared to the theoretical calculations based on electrostatic modelling with a tunnel coupling ratio ( [symbol] v/w [symbol] =2.08. Excellent agreement is found between the experimental and theoretical values. Small discrepancies (<1 meV) are most likely due to small misalignments of the quantum dot electrochemical potentials, which gives rise to on-site disorder, that causes small shifts in the conductance peaks such that the peak structure is no longer symmetric around zero.

FIG. 10E shows the topological phase of the SSH model for Device II. The blue line in FIG. 10E represents the theoretical fit to the experiment, with a tunnel coupling ratio [symbol] v/w [symbol] =0.265. A similar voltage range scan as for Device I but here it may be observed that two sets of closely spaced peaks at zero gate voltage and at 85.5 mV corresponding to the average on-site energies across the array, [symbol] U [symbol] =22.0±3.2 meV. The conductance peaks from the states away from quarter-filling are not visible since they are now delocalised within the bulk of the array with a low probability of existing at the edge quantum dots. As a result, tunnelling between these bulk-like states and the source/drain leads is significantly suppressed. In the topological phase the quarter-filling gap almost disappears completely with a sharp transition from the m+4 to m+6 states given by only two conductance peaks separated by ˜0.2 meV shown in FIG. 10F. These electron states correspond to where there are no electrons (m+4 electrons) on the edge quantum dots to where both dots are occupied (m+6 electrons). Importantly at exactly quarter-filling (m+5 electrons) there is a non-zero probability that either 4 (P≈0.05), (P≈0.30 or ≈0.60 due to the two-fold degeneracy) or 6 (P≈0.05) electrons exist on the array at the same time due to the nearly-fourfold degenerate ground state, as illustrated in FIG. 10G.

This remarkable observation, that at zero gate bias there is a superposition of the number of electrons on the edge quantum dots, is a direct result of the near-zero energy of the topological states of the array and is a distinctive property of the many-body SSH model. Since these topological states are localised at the edge quantum dots, the current owing through the array corresponds to an electron moving from one side of the array to the other without occupying any of the inner quantum dots. This unique property is a direct consequence of the topology embedded within the SSH model as confirmed by the double conductance peak in FIG. 9E.

### Simulating the Equilibrium Voltages in Batteries Using Method 400 and Method 500

In this section, methods 400 and 500 will be explained with respect to the example of simulating interfaces. In this embodiment, the computational problem to be solved relates to simulating behaviour of one or more interfaces.

An interface is the region formed between two systems. In particular, between two different crystal structures or phases. Understanding the behaviour of interfaces is important in many materials science problems. Current methods for simulating interfaces use density functional theory (DFT). Such methods often must balance high computational cost and simplifying approximations. Aspects of the present disclosure overcome these disadvantages by allowing direct simulation of specific interfaces through the fabrication of AQSs.

An AQS with an interface is comprised of at least two different quantum dot structures. The left panel of FIG. 11 shows four different interfaces between two systems (1110, 1120, 1130 and 1140). In this example the two systems are two different quantum dot array structures. These two quantum dot arrays are denoted by the light and dark shaded areas—or array 1 and array 2.

In system 1110 there are two different quantum dot arrays side by side. There is one interface-forming a line between the two arrays. This interface is highlighted by the dashed line box 1112. In system 1120 there are again two different quantum dot arrays-one rectangle nestled inside another. There is one interface-forming a rectangle between the two arrays. This interface is highlighted by the dashed line box 1122. Systems 1130 and 1140 show example interfaces for different arrangements of two quantum dots array systems. In each case, the interface is highlighted by the dashed rectangle 1132 and 1142, respectively.

The right panel of FIG. 11 shows a zoomed in view of interfaces 1112, 1122, 1132, 1142. In one example the interface may have no disorder 1150. In this case, there is a clear demarcation between the two systems. In this example, the quantum dots of array 1 are represented by the larger circles and the quantum dots of array 2 are represented by smaller circles. In a system with a no disorder interface array 1 is on the left comprising a first plurality of quantum dots and array two is on the right comprising a second plurality of quantum dots, and there is no mixing between the two.

In one example, the difference between the two quantum dot arrays may be the size of the quantum dots. In other examples, the difference between the two quantum dot arrays may be the array structure, eg array 1 is a square lattice and array 2 is a triangular lattice. It will be appreciated that the arrays can be formed from arbitrary combinations of quantum dot size, shape and number, inter-dot separations, and geometry of the lattice.

Another type of interface is an atomic disorder interface 1160. In this example, the interface between array 1 and array 2 may not be clearly separable. Rather, the interface comprises a random admixture of quantum dots of array 1 and the quantum dots of array 2.

Yet another type of interface is one comprising continuous disorder 1170. In this example, array 1 merges into array 2 in a continuous manner. For example, array I may be an array comprising a 4P quantum dots on a square lattice and array 2 may comprise a square array of 1P quantum dots. As such, the interface comprises quantum dots of 2P and 3P on a square lattice.

It will be appreciated that the disorder of an interface may be precisely controlled through the fabrication process of the AQS.

It will be appreciated that FIG. 11 illustrates example interfaces between two quantum dot arrays. However, this can be extended to include devices with M systems and at least M+1 interfaces.

Method 400 can be used for determining fabrication parameters for an AQS to simulate interfaces.

At step 402 of method 400 the measurement method is identified. In the case of simulating interfaces the measurement method required to obtain a solution may be obtained using the method 3 (see Table A) based on a four-point probe measurement. For example using the Hall bar geometry. The Hall bar geometry allows for direct measurement of the voltage and/or capacitance of the interface of very large quantum dot arrays. These measurements are useful for a number of important material properties of interfaces for electronics.

Next at step 404, the computational problem of simulating one or more interfaces is mapped to the general Hubbard Hamiltonian of equation 1. In particular, each quantum dot array may be mapped onto the Hubbard Hamiltonian of equation 1 to yield a mapped Hamiltonian corresponding to each quantum dot array.

Next at step 406 of the method, the device fabrication parameters are identified based on the measurement method and the mapped Hamiltonian.

Since a Hall bar measurement, a specific example of a four-point probe measurement, was identified as the measurement method at least one source lead and at least one drain lead are required. Further, in order to measure the voltage drop across the interface at least two gate electrodes are needed for each quantum dot array. The quantum dot array parameters depend on the mapped Hamiltonian corresponding to the quantum dot array.

After method 400 is performed, an AQS 200 may be fabricated using the identified device fabrication parameters.

Once an AQS 200 is fabricated, the AQS 200 can be used to simulate the computational problem using method 500.

In one embodiment, the problem of simulating an interface may be related to simulating the voltages between electrodes in a battery. Battery usage is increasing in the technology driven modern world, with mobile systems such as electric vehicles, smart phones, laptops etc. all rely on stored energy to operate. As such, there is a need to produce improved batteries that can last longer, store more energy and are cost effective to manufacture. In order to achieve, this it is important to be able to accurately model different batteries in order to optimise performance.

Method 400 may be used to fabricate an AQS for simulating batteries to determine the equilibrium voltage. For example, an AQS may be fabricated to simulate electrodes in a Lithium-ion battery. In this example, the measurement method is a four-point probe measurement, for example the Hall effect (step 402).

Next at step 404, the Hamiltonian is generated based on the computational problem of simulating a battery. The (2D) crystal energies can be described using the Hubbard model of equation 1, which can be directly simulated in the AQS by judicious choice of the interaction and hopping amplitudes. This is performed by taking the crystal Hamiltonian (chemistry Hamiltonian) and mapping it in a low-energy (Hubbard) Hamiltonian (see equation 1) to simulate. The global phase of the system, that is the global condensed matter phase eg, superconductor, metallic etc, can then be simulated. This method greatly reduces the computational complexity in determining the energy of the crystals.

Next at step 406 the device fabrication parameters are identified based on the use of the Hall effect measurement and the mapped Hamiltonian.

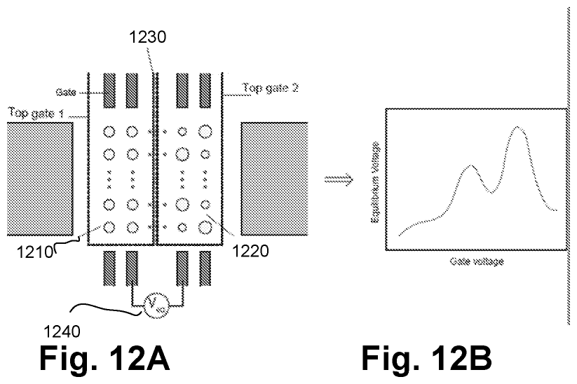

FIG. 12A shows an example AQS for simulating the interface between two quantum dot arrays 1210 and 1220. The interface between the two quantum dot arrays is represented by 1230. For example, 2D array 1210 may represent the cathode and 2D array 1220 represents the anode of a battery. The electrochemical behaviour of a battery may be directly simulated via a four-point probe measurement-for example using a 4-point measurement in a Hall bar geometry—see FIG. 12A. By positioning voltage (Hall) probes on either side of the interface 1230 between the cathode 1210 and anode 1220, the voltage difference between them can be directly measured.

This voltage drop across interface 1230 is a direct measurement of the equilibrium voltage (V_{eq}) produced from an electrochemical cell. The doping in the arrays may be varied to examine how the potential changes as a function of charge density. This may be used to infer information about the battery performance over time. To vary the doping concentration the gates on top of the array may be varied to change the electron occupation.

The equilibrium voltage, V_{eq} produced from an electrochemical cell can be found using the Nernst equation, V_{eq}=−ΔG/nF where ΔG is the change in free energy with the reaction present in the electrochemical cell, n is the number of charges transferred in the reaction, and F is the Faraday constant. This equation can be simplified under certain conditions (eg, low temperature, full discharge/charge cycle average) to,

$${V}_{e q} = - \frac{[ {E}_{Reactants} - {E}_{Products} ]}{n F} .$$

Taking as an example, LiCoO₂ as the cathode and metallic Li as the anode, the equilibrium voltage is found to be,

$${V}_{e q} = - \frac{[ {E}_{L i C o {O}_{2}} - {E}_{{CoO}_{2}} - {E}_{L i} ]}{F} .$$

Which ultimately requires determining the energy of the LiCoO₂ crystal with and without Li ions present. These energies are traditionally found using DFT requiring significant resources and lacking sufficient accuracy.

Further, the atomic-scale control over the interface 1230 between the cathode 1210 and anode 1220 can also be leveraged to examine the effect of disorder on the equilibrium voltage. At the interface 1230, intentional defects can be added to determine how important the materials' interface is for the generated voltage of the battery—see 1160, 1170 for example disorder.

Once method 400 is complete, an AQS may be fabricated suitable for simulating a battery.

Next, example method 500 may be used to use the AQS to simulate a battery.

At step 502, a selected measurement method is applied to measure a selected property of the AQS. Measuring the voltage drop 1240 across interface 1230 would be a direct measurement of V_{eq}. This simulation makes use of the transport of electrons as charge carriers instead of Li ions, for example.

The measurement may be performed by applying a current through the source and drain leads and monitoring the voltages on each of the gates on each side of the interface. By looking at the potential difference between the gates V_{eq} can be directly measured.

Next, at step 504 the measured data—the equilibrium voltage—are interpreted (analyzed) to determine the solution the interface problem. FIG. 12B shows a plot of the equilibrium voltage data as a function of gate voltage. This method allows for direct simulation of V_{eq} which is important for designing new cathode and anode materials for all types of batteries. Accurate calculations of this value can be used instead of physically making the different materials (which would require extensive research and development for a single cathode). This calculation is essentially a quantum chemistry calculation (one of the main applications of quantum computing) where the variable of interest, V_{eq} may be directly determined.

Gate voltages could be used to control the doping in each side of the cathode 1210 and anode 1220 to simulate the reaction dynamics. By reducing the charge carriers in the anode 1220 (electrons, analogous to Li ions in the cathode 1210 of the electrochemical cell), the depletion of the battery can be simulated to determine how the equilibrium voltage varies during the discharge cycle of the battery—see FIG. 12B.

It will be appreciated that similar methods can be used to examine the capacitance in supercapacitors by performing capacitance measurements. However, the Hamiltonian and lattice structure will need to be different to reflect the different geometry of the supercapacitors. This geometry can be different depending on the exact mechanism of supercapacitor that is under investigation. The charging of the capacitor can be performed by tuning gate voltages to add more electrons to the lattice to build up an electrostatic charge.

1. A method for fabricating an analogue quantum system, the method comprising:
generating a Hamiltonian based on a computational problem in respect of which a solution is sought using one or more identified measurement methods;
identifying analogue quantum system fabrication parameters for the analogue quantum system based on the one or more identified measurement methods and the Hamiltonian; and
fabricating the analogue quantum system based on the identified analogue quantum system fabrication parameters.

2. The method of claim 1, wherein the method further comprises identifying the one or more measurement methods to obtain the solution for the computational problem.

3. The method of claim 1 or 2, wherein the one or more measurement methods is selected from a list comprising at least one of:
measuring ground state energy of an array of quantum dots of the analogue quantum system;
measuring electron transmission probability between source and drain leads of the analogue quantum system;
measuring a voltage and/or capacitance across the array of quantum dots of the analogue quantum system using a four-point probe measurement; and
measuring electron occupation in one or more quantum dots of an array of quantum dots of the analogue quantum system.

4. The method of any one of claims 1 to 3, wherein the system fabrication parameters include at least one of:
number of control gates of the analogue quantum system;
number of source leads of the analogue quantum system;
number of drain leads of the analogue quantum system;
number of charge sensors of the analogue quantum system;
the dimensionality of the analogue quantum system;
number and/or geometry of the quantum dots in the quantum dot array of the analogue quantum system;
separation between adjacent quantum dots in the quantum dot array of the analogue quantum system;
temperature of the analogue quantum system; and
detuning of the analogue quantum system.

5. A method for fabricating an analogue quantum system for simulating a battery, the method comprising:
generating a Hamiltonian based on the computational problem of simulating the battery;
identifying system fabrication parameters for the analogue quantum system based on the Hamiltonian and measuring a voltage and/or capacitance between a first quantum dot array and a second quantum dot array using a four-point probe measurement; and
fabricating the analogue quantum system based on the identified system fabrication parameters.

6. The method of claim 5, wherein the system fabrication parameters include at least one of:
number of control gates of the analogue quantum system;
number of source leads of the analogue quantum system;
number of drain leads of the analogue quantum system;
number of charge sensors of the analogue quantum system;
the dimensionality of the first and second quantum dot arrays of the analogue quantum system;
number and/or geometry of the quantum dots in the first and second quantum dot arrays;
separation between adjacent quantum dots in the first and second quantum dot arrays;
temperature of the analogue quantum system; and
detuning of the analogue quantum system.

7. A method for fabricating an analogue quantum system for simulating at least one interface, the method comprising:
generating a Hamiltonian based on the computational problem of simulating an interface;
identifying system fabrication parameters for the analogue quantum system based on the Hamiltonian and measuring a voltage and/or capacitance between at least one interface between a first quantum dot array and a second quantum dot array using a four-point probe measurement; and
fabricating the analogue quantum system based on the identified system fabrication parameters.

8. The method of claim 7, wherein the system fabrication parameters include at least one of:
number of control gates of the analogue quantum system;
number of source leads of the analogue quantum system;
number of drain leads of the analogue quantum system;
number of charge sensors of the analogue quantum system;
the dimensionality of the at least two quantum dot arrays of the analogue quantum system;
number and/or geometry of the quantum dots in the at least two quantum dot arrays;
separation between adjacent quantum dots in the at least two quantum dot arrays;
temperature of the analogue quantum system; and
detuning of the analogue quantum system.

9. The method of any one of claims 1-8, wherein fabricating the analogue quantum system comprises:
preparing a bulk layer of a semiconductor substrate;
exposing a clean crystal surface of the semiconductor layer to dopant molecules to produce an array of dopant dots on the exposed surface;
annealing the arrayed surface to incorporate the dopant dots into the semiconductor layer; and
forming one or more control gates, source and drain leads.

10. The method of claim 9, wherein the one or more control gates are formed in a same plane as the dopant dots.

11. The method of claim 9, further comprising depositing a dielectric material above the annealed second semiconductor layer, wherein the one or more control gates are formed above the dielectric material.

12. The method of claim 9, further comprising forming one or more charge sensors in the analogue quantum system to sense the charge of the one or more dopant dots.

13. A method for solving a computational problem, the method comprising:
providing an analogue quantum system comprising:
an array of quantum dots simulating a Fermi-Hubbard model,
a plurality of control gates to vary the Hubbard Hamiltonian parameters, and
one or more source and drain leads to measure the current through the array of quantum dots;
applying a selected measurement method to measure one or more properties of the analogue quantum system; and
interpreting the measured one or more properties of the analogue quantum system to determine a solution to the computational problem.

14. The method of claim 13, wherein the computational problem is a simulation problem or an optimization problem.

15. The method of claim 13, wherein the selected measurement method is at least one of:
measuring ground state energy of an array of quantum dots of the analogue quantum system;
measuring electron transmission probability between source and drain leads of the analogue quantum system;
measuring a voltage and/or capacitance across the array of quantum dots of the analogue quantum system using a four-point probe measurement; or
measuring electron occupation in one or more quantum dots of the array of quantum dots of the analogue quantum system.

16. The method of claim 15, wherein measuring ground state energy of the array of quantum dots comprises identifying an energy gap between adjacent measured conduction peaks.

17. The method of claim 15, wherein measuring the electron transmission probability comprises identifying the height of measured conduction peaks.

18. A method for solving a computational problem of simulating a battery, the method comprising:
providing an analogue quantum system comprising:
at least two arrays of quantum dots simulating a Fermi-Hubbard model,
a plurality of control gates to vary Hubbard Hamiltonian parameters, and
one or more source and drain leads to measure the current through the array;
measuring a voltage and/or capacitance, using a four-point probe measurement, between the first quantum dot array and the second quantum dot array; and
interpreting the measured voltage and/or capacitance of the analogue quantum system to determine a solution to the computational problem.

19. A method for solving a computational problem of simulating at least one interface, the method comprising:
providing an analogue quantum system comprising:
at least two arrays of quantum dots simulating a Fermi-Hubbard model,
an interface defined between the at least two arrays of quantum dots;
a plurality of control gates to vary the Hubbard Hamiltonian parameters, and
one or more source and drain leads to measure the current through the at least two arrays of quantum dots;
applying a four-point probe measurement to measure a voltage and/or capacitance across the interface; and
interpreting the measured voltage and/or capacitance of the analogue quantum system to determine a solution to the computational problem of simulating at least one interface.

20. The method of any one of claim 13, 18 or 19, wherein the plurality of control gates vary the electrochemical potentials of the quantum dots and/or tunnel couplings between the quantum dots.

21. The method of any one of claims 13-20, wherein the analogue quantum system includes at least one charge sensor to measure the electron occupation in one or more quantum dots of the array.

22. The method of any one of claims 13-20, wherein the quantum dots are donor-doped silicon quantum dots.

23. The method of any one of claims 13-20, wherein the array is fabricated using scanning tunneling microscopy.

24. The method of any one of claims 13-20, wherein the array is one, two or three-dimensional.

25. An analogue quantum system fabricated according to the method of any one of claims 1-12.
